(19) United States
(12) Patent Application Publication
(10) Pub. No.: US 2015/0287817 A1
(43) Pub. Date: Oct. 8, 2015

(54) SILICON CARBIDE SEMICONDUCTOR DEVICE AND METHOD FOR MANUFACTURING SAME

(71) Applicant: Sumitomo Electric Industries, Ltd., Osaka-shi (JP)

(72) Inventors: Ryosuke Kubota, Osaka-shi (JP); Toru Hiyoshi, Osaka-shi (JP); Ren Kimura, Osaka-shi (JP)

(21) Appl. No.: 14/418,063

(22) PCT Filed: Sep. 17, 2013
(86) PCT No.: PCT/JP2013/074984

§ 371 Date: Jan. 28, 2015

(30) Foreign Application Priority Data
Sep. 24, 2012 (JP) 2012-209388

(51) Int. Cl. H01L 29/78; H01L 29/36; H01L 21/266; H01L 29/10; H01L 21/265; H01L 29/16; H01L 29/66

(52) U.S. Cl. CPC H01L 29/7802; H01L 29/1608; H01L 29/36; H01L 29/66068; H01L 29/66712; H01L 29/1095; H01L 21/26513; H01L 21/266

(57) ABSTRACT

A first portion of a silicon carbide substrate having an impurity of a first conductivity type is disposed deeper than a first depth position. A second portion is disposed to extend from the first depth position to a second depth position shallower than the first depth position. A third portion is disposed to extend from the second depth position to a main surface. The second portion has a second impurity concentration higher than a first impurity concentration of the first portion. The third portion has a third impurity concentration not less than the first impurity concentration and less than the second impurity concentration. A body region having an impurity of a second conductivity type has an impurity concentration peak at a depth position shallower than the first depth position and deeper than the second depth position.

### TECHNICAL FIELD

The present invention relates to a silicon carbide semiconductor device and a method for manufacturing the silicon carbide semiconductor device, in particular, a silicon carbide semiconductor device having a gate electrode and a method for manufacturing such a silicon carbide semiconductor device.

### BACKGROUND ART

Japanese Patent Laying-Open No. 10-242458 (Patent Document 1) discloses a MOSFET (Metal Oxide Semiconductor Field Effect Transistor). This MOSFET includes: a drift region having a first conductivity type; a base region having a second conductivity type and selectively formed in one main surface of the drift region; and a source region having the first conductivity type and selectively formed in the base region. This MOSFET also includes an impurity region that is disposed at a side surface of the base region, that has the first conductivity type, and that has an impurity added therein at a higher concentration than that in the drift region. This publication describes that on-voltage can be made low by rendering a JFET resistance (JFET effect) small in the MOSFET.

### CITATION LIST

### Patent Document

PTD 1: Japanese Patent Laying-Open No. 10-242458

### SUMMARY OF INVENTION

### Technical Problem

According to the technique of the publication, the high concentration region for reducing the JFET resistance is formed at the side surface of the base region. Since the side surface of the base region reaches a surface of the substrate, the high concentration region reaches the surface of the substrate and therefore makes contact with a gate insulating film. In the high concentration region, a depletion layer is less likely to be formed, so that a high electric field is likely to be applied to the gate insulating film making contact with the high concentration region. As a result, dielectric breakdown of the gate insulating film is likely to take place. This makes it difficult to provide the semiconductor device with a sufficiently high breakdown voltage.

The present invention has been made to solve such a problem and has its object to provide a silicon carbide semiconductor device having a high breakdown voltage and a low on-resistance, as well as a method for manufacturing such a silicon carbide semiconductor device.

### Solution to Problem

A silicon carbide semiconductor device of the present invention includes a silicon carbide substrate, a body region, a source region, a gate insulating film, a gate electrode, a first main electrode, and a second main electrode. The silicon carbide substrate has a first main surface and a second main surface opposite to the first main surface. The silicon carbide substrate has an impurity for providing a first conductivity type. The silicon carbide substrate has first to third portions. The first portion is disposed deeper than a first depth position based on the second main surface as a reference. The second portion is disposed to extend from the first depth position to a second depth position shallower than the first depth position. The third portion is disposed to extend from the second depth position to the second main surface. The first to third portions respectively have first to third impurity concentrations. The second impurity concentration is higher than the first impurity concentration. The third impurity concentration is not less than the first impurity concentration and is less than the second impurity concentration. The body region is provided on a portion of the second main surface of the silicon carbide substrate. The body region has an impurity for providing a second conductivity type. The body region has a concentration peak of the impurity, for providing the second conductivity type, at a depth position shallower than the first depth position and deeper than the second depth position. The source region is provided on a portion of the body region. The source region has the first conductivity type. The gate insulating film is provided on the body region to connect a portion, which has the first conductivity type in the silicon carbide substrate, and the source region to each other. The gate electrode is provided on the gate insulating film. The first main electrode is provided on the first main surface of the silicon carbide substrate. The second main electrode is in contact with the source region.

According to the silicon carbide semiconductor device, because the impurity concentration of the first portion is made lower than the impurity concentration of the second portion in the silicon carbide substrate, the depletion layer is facilitated to extend in the first portion. Accordingly, dielectric breakdown of the silicon carbide substrate is suppressed. Further, because the impurity concentration of the third portion is made lower than the impurity concentration of the second portion in the silicon carbide substrate, the depletion layer is facilitated to extend in the third portion. This reduces the electric field applied to the gate insulating film facing the third portion. Accordingly, dielectric breakdown of the gate insulating film is suppressed. That is, the dielectric breakdown is suppressed in each of the silicon carbide substrate and the gate insulating film. Accordingly, the breakdown voltage of the silicon carbide semiconductor device can be improved. Moreover, according to the silicon carbide semiconductor device, the impurity concentration of the second portion is made higher than the impurity concentration of the first portion in the silicon carbide substrate. Accordingly, the depletion layer can be suppressed from extending from the body region, which has an impurity concentration peak at a depth position corresponding to the second portion, to the second portion. This leads to a low on-resistance of the silicon carbide semiconductor device. As described above, according to the silicon carbide semiconductor device of the present invention, a high breakdown voltage and a low on-resistance are obtained.

In the silicon carbide semiconductor device, the second portion of the silicon carbide substrate may contain an impurity provided by ion implantation. Accordingly, the impurity concentration of the second portion can be improved through the ion implantation. That is, the second portion can be formed using the ion implantation.

In the silicon carbide semiconductor device, the third impurity concentration may be equal to the first impurity concentration. Accordingly, the impurity concentration of the third portion can be equal to the impurity concentration of the first portion in the silicon carbide substrate. Hence, in the manufacturing method, the first to third portions can be provided only by forming an epitaxial layer having a concentration common to the first impurity concentration and the third impurity concentration and then performing the implantation to increase the impurity concentration of the second portion. This more simplifies the method for manufacturing the silicon carbide semiconductor device.

In the silicon carbide semiconductor device, the third impurity concentration may be higher than the first impurity concentration. Accordingly, the resistance of the third portion of the silicon carbide substrate can be made smaller. Accordingly, the on-resistance of the silicon carbide semiconductor device can be made lower.

In the silicon carbide semiconductor device, the third portion of the silicon carbide substrate may have a thickness of not less than 5 nm and not more than 10 nm. Because the third portion has a thickness of not less than 5 nm, the electric field applied to the gate insulating film facing the third portion can be made smaller. Because the third portion has a thickness of not more than 10 nm, the second portion having a resistivity lower than that in the third portion is provided up to a shallower position, so that the on-resistance of the silicon carbide semiconductor device can be made lower.

A method for manufacturing a silicon carbide semiconductor device according to one aspect of the present invention has the following steps. There is prepared a silicon carbide substrate having a first main surface and a second main surface opposite to the first main surface and having an impurity for providing a first conductivity type. The impurity for providing the first conductivity type is implanted into the second main surface of the silicon carbide substrate such that a dose amount per volume in a region from a first depth position to a second depth position shallower than the first depth position becomes larger than each of a dose amount per volume in a region deeper than the first depth position and a dose amount per volume in a region from the second main surface to the second depth position. An impurity for providing a second conductivity type is implanted into the second main surface of the silicon carbide substrate such that a body region having the second conductivity type is formed in a portion of the second main surface of the silicon carbide substrate. The step of implanting the impurity for providing the second conductivity type is performed such that the dose amount per volume has a peak between the first depth position and the second depth position. A source region having the first conductivity type is formed by implanting the impurity for providing the first conductivity type into a portion of one of the body region and a region to serve as the body region. A gate insulating film is formed on the body region to connect a portion, which has the first conductivity type in the silicon carbide substrate, and the source region to each other. A gate electrode is formed on the gate insulating film. A first main electrode is formed on the first main surface of the silicon carbide substrate. A second main electrode is formed in contact with the source region.

According to the manufacturing method according to the one aspect described above, the first to third portions are provided as a result of the implantations of impurities in the silicon carbide substrate. The first portion is disposed deeper than the first depth position based on the second main surface as a reference. The second portion is disposed to extend from the first depth position to the second depth position shallower than the first depth position. The third portion is disposed to extend from the second depth position to the second main surface. The first to third portions respectively have the first to third impurity concentrations. The second impurity concentration is higher than the first impurity concentration. The third impurity concentration is not less than the first impurity concentration and is less than the second impurity concentration. Moreover, the body region is formed to have the concentration peak of the impurity, for providing the second conductivity type, at the depth position shallower than the first depth position and deeper than the second depth position. Further, because the impurity concentration of the first portion is made lower than the impurity concentration of the second portion in the silicon carbide substrate, the depletion layer is facilitated to extend in the first portion. Accordingly, dielectric breakdown of the silicon carbide substrate is suppressed. Further, because the impurity concentration of the third portion is made lower than the impurity concentration of the second portion in the silicon carbide substrate, the depletion layer is facilitated to extend in the third portion. This reduces the electric field applied to the gate insulating film facing the third portion. Accordingly, dielectric breakdown of the gate insulating film is suppressed. That is, the dielectric breakdown is suppressed in each of the silicon carbide substrate and the gate insulating film. Accordingly, the breakdown voltage of the silicon carbide semiconductor device can be improved. Moreover, according to the silicon carbide semiconductor device, the impurity concentration of the second portion is made higher than the impurity concentration of the first portion in the silicon carbide substrate. Accordingly, the depletion layer can be suppressed from extending from the body region, which has an impurity concentration peak at a depth position corresponding to the second portion, to the second portion. This leads to a low on-resistance of the silicon carbide semiconductor device. As described above, according to the manufacturing method, a high breakdown voltage and a low on-resistance are obtained. Moreover, according to the manufacturing method, a difference in impurity concentration among the first to third portions in the silicon carbide substrate can be adjusted through the implantations of impurities.

In the manufacturing method according to the above-described one aspect, the step of implanting the impurity for providing the first conductivity type into the second main surface of the silicon carbide substrate may be performed without using an implantation mask. This more simplifies the manufacturing method.

In the manufacturing method according to the above-described one aspect, the step of implanting the impurity for providing the first conductivity type into the second main surface of the silicon carbide substrate may be performed using an implantation mask that covers at least a portion of one of the body region and a region to serve as the body region. Accordingly, in the body region, the impurities for providing the first and second conductivity types are canceled with each other at a smaller degree. In other words, an amount of impurities providing substantially no contribution to the conductivity types can be reduced. Therefore, the channel resistance on the body region can be made low, so that the on-resistance of the silicon carbide semiconductor device can be made lower.

A method for manufacturing a silicon carbide semiconductor device according to another aspect of the present invention has the following steps. There is prepared a silicon carbide substrate having a first main surface and a second main surface opposite to the first main surface and having an impurity for providing a first conductivity type. The silicon carbide substrate includes a first portion, a second portion, and a third portion, the first portion being disposed deeper than a first depth position based on the second main surface as a reference, the second portion being disposed to extend from the first depth position to a second depth position shallower than the first depth position, the third portion being disposed to extend from the second depth position to the second main surface. The first to third portions respectively have first to third impurity concentrations. The second impurity concentration is higher than the first impurity concentration. The third impurity concentration is not less than the first impurity concentration and is less than the second impurity concentration. The step of preparing the silicon carbide substrate includes the steps of: epitaxially growing the first portion on a single-crystal substrate to have the first impurity concentration; epitaxially growing the second portion on the first portion to have the second impurity concentration; and epitaxially growing the third portion on the second portion to have the third impurity concentration. An impurity for providing a second conductivity type is implanted into the second main surface of the silicon carbide substrate such that a body region having the second conductivity type is formed in a portion of the second main surface of the silicon carbide substrate. The step of implanting the impurity for providing the second conductivity type is performed such that a dose amount per volume has a peak between the first depth position and the second depth position. A source region having the first conductivity type is formed by implanting the impurity for providing the first conductivity type into a portion of one of the body region and a region to serve as the body region. A gate insulating film is formed on the body region to connect a portion, which has the first conductivity type in the silicon carbide substrate, and the source region to each other. A gate electrode is formed on the gate insulating film. A first main electrode is formed on the first main surface of the silicon carbide substrate. A second main electrode is formed in contact with the source region.

According to the manufacturing method according to the above-described another aspect, because the impurity concentration of the first portion is made lower than the impurity concentration of the second portion in the silicon carbide substrate, the depletion layer is facilitated to extend in the first portion. Accordingly, dielectric breakdown of the silicon carbide substrate is suppressed. Further, because the impurity concentration of the third portion is made lower than the impurity concentration of the second portion in the silicon carbide substrate, the depletion layer is facilitated to extend in the third portion. This reduces the electric field applied to the gate insulating film facing the third portion. Accordingly, dielectric breakdown of the gate insulating film is suppressed. That is, the dielectric breakdown is suppressed in each of the silicon carbide substrate and the gate insulating film. Accordingly, the breakdown voltage of the silicon carbide semiconductor device can be improved. Moreover, according to the silicon carbide semiconductor device, the impurity concentration of the second portion is made higher than that of the first portion in the silicon carbide substrate. Accordingly, the depletion layer can be suppressed from extending from the body region, which has an impurity concentration peak at a depth position corresponding to the second portion, to the second portion. This leads to a low on-resistance of the silicon carbide semiconductor device. As described above, according to the manufacturing method, a high breakdown voltage and a low on-resistance are obtained. Moreover, according to the manufacturing method, a difference in impurity concentration among the first to third portions in the silicon carbide substrate can be adjusted during each of the epitaxial growths of the first to third portions.

### Advantageous Effects of Invention

As apparent from the description above, according to the present invention, a high breakdown voltage and a low on-resistance are obtained.

### BRIEF DESCRIPTION OF DRAWINGS

FIG. 1 is a partial cross sectional view schematically showing a configuration of a silicon carbide semiconductor device in a first embodiment of the invention of the present application.

FIG. 2 is a graph showing an exemplary impurity concentration profile in the depth direction indicated by an arrow Z of FIG. 1.

FIG. 3 is a partial cross sectional view schematically showing a first step of a method for manufacturing the silicon carbide semiconductor device of FIG. 1.

FIG. 4 is a partial cross sectional view schematically showing a second step of the method for manufacturing the silicon carbide semiconductor device of FIG. 1.

FIG. 5 is a partial cross sectional view schematically showing a third step of the method for manufacturing the silicon carbide semiconductor device of FIG. 1.

FIG. 6 is a partial cross sectional view schematically showing a fourth step of the method for manufacturing the silicon carbide semiconductor device of FIG. 1.

FIG. 7 is a partial cross sectional view schematically showing a fifth step of the method for manufacturing the silicon carbide semiconductor device of FIG. 1.

FIG. 8 is a partial cross sectional view schematically showing a sixth step of the method for manufacturing the silicon carbide semiconductor device of FIG. 1.

FIG. 9 is a partial cross sectional view schematically showing a seventh step of the method for manufacturing the silicon carbide semiconductor device of FIG. 1.

FIG. 10 is a partial cross sectional view schematically showing an eighth step of the method for manufacturing the silicon carbide semiconductor device of FIG. 1.

FIG. 11 is a partial cross sectional view schematically showing a ninth step of the method for manufacturing the silicon carbide semiconductor device of FIG. 1.

FIG. 12 is a partial cross sectional view schematically showing a tenth step of the method for manufacturing a silicon carbide semiconductor device of FIG. 1.

FIG. 13 is a partial cross sectional view schematically showing one step of a method for manufacturing a silicon carbide semiconductor device in a second embodiment of the invention of the present application.

FIG. 14 is a partial cross sectional view schematically showing one step of a method for manufacturing a silicon carbide semiconductor device in a third embodiment of the invention of the present application.

FIG. 15 is a graph showing an impurity concentration profile as a modification of FIG. 2.

### DESCRIPTION OF EMBODIMENTS

The following describes embodiments of the present invention with reference to figures. It should be noted that in the below-mentioned figures, the same or corresponding portions are given the same reference characters and are not described repeatedly.

### First Embodiment

As shown in FIG. 1, a silicon carbide semiconductor device of the present embodiment is, in particular, a MOSFET 100 suitable for a power semiconductor device. More specifically, MOSFET 100 is a vertical type DiMOSFET (Double-Implanted MOSFET). MOSFET 100 (silicon carbide semiconductor device) includes an epitaxial substrate 39 (silicon carbide substrate), body regions 32, source regions 33, contact regions 34, a gate oxide film 41 (gate insulating film), a gate electrode 42, an interlayer insulating film 43, a drain electrode 61 (first main electrode), source electrodes 51 (second main electrode), and a source interconnection layer 52.

Epitaxial substrate 39 has a backside surface P1 (first main surface) and an upper surface P2 (second main surface) opposite to backside surface P1. Epitaxial substrate 39 is provided with an impurity for providing n type (first conductivity type) conductivity, i.e., is provided with a donor. Epitaxial substrate 39 has a single-crystal substrate 30 and a silicon carbide layer provided thereon. This silicon carbide layer includes a drift region 31 having n type conductivity. Drift region 31 has a breakdown voltage holding portion 31a (first portion), a JFET portion 31b (second portion), and a surface portion 31c (third portion). In the present embodiment, JFET portion 31b contains an impurity provided through ion implantation. It should be noted that a buffer layer may be provided between the silicon carbide layer and single-crystal substrate 30.

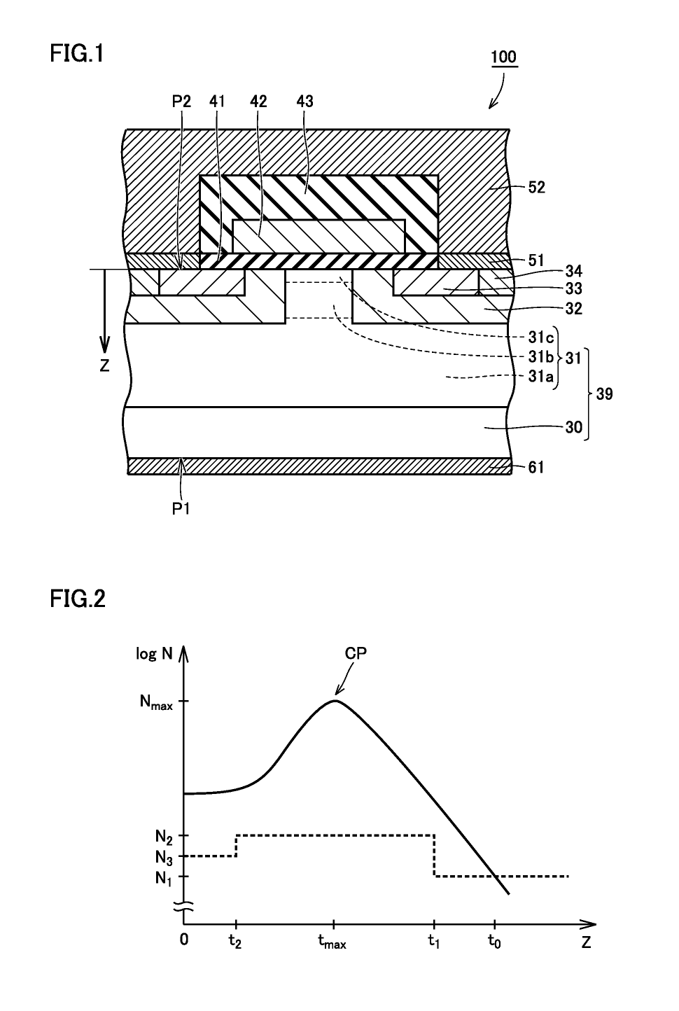

Referring to the profile (FIG. 2) of an impurity concentration N in the depth direction indicated by an arrow Z (FIG. 1), breakdown voltage holding portion 31a is disposed deeper than a depth position t₁ (first depth position) based on upper surface P2 as a reference. JFET portion 31b is disposed to extend from depth position t₁ to a depth position t₂ (second depth position) shallower than depth position t₁. Surface portion 31c is disposed to extend from depth position t₂ to upper surface P2. Preferably, depth position t₂ is not less than about 5 nm and not more than about 10 nm. In other words, surface portion 31c preferably has a thickness of not less than about 5 nm and not more than about 10 nm.

Breakdown voltage holding portion 31a, JFET portion 31b, and surface portion 31c respectively have impurity concentrations N₁ to N₃ (first to third impurity concentrations). Impurity concentration N₂ is higher than impurity concentration N₁. Impurity concentration N₃ is not less than impurity concentration N₁ and is less than impurity concentration N₂. Preferably, impurity concentration N₃ is 80% or less of impurity concentration N₂. In the present embodiment, impurity concentration N₃ is higher than impurity concentration N₁.

Each of impurity concentrations N₁ and N₃ is preferably not less than about 1×10¹⁴ cm⁻³ and not more than about 1×10¹⁷ cm⁻³. Impurity concentration N₂ is preferably not less than about 6×10¹⁵ cm⁻³ and not more than about 1×10¹⁷ cm⁻³. For example, impurity concentration N₁ is about 5×10¹⁵ cm⁻³, impurity concentration N₂ is about 8×10¹⁵ cm⁻³, and impurity concentration N₃ is between them.

Each of body regions 32 is provided on a portion of upper surface P2 of epitaxial substrate 39. Body region 32 is provided with an impurity for providing p type (second conductivity type different from the first conductivity type) conductivity, i.e., is provided with an acceptor. This impurity is, for example, aluminum (Al) or boron (B). Body regions 32 sandwich each of JFET portion 31b and surface portion 31c. An interval between body regions 32 (dimension in the lateral direction of FIG. 1) is, for example, not less than 1 μm and not more than 5 μm.

Each of body regions 32 has an acceptor concentration peak CP at a depth position tₘₐₓ, which is shallower than a depth position t₁ and is deeper than a depth position t₂. An impurity concentration Nₘₐₓ at concentration peak CP is preferably not less than about 1×10¹⁸ cm³. Impurity concentration Nₘₐₓ is preferably 100 times as large as each of impurity concentrations N₁ to N₃. A depth position t₀ reached by body region 32 is not less than about 0.5 μm and not more than about 1 μm, for example.

Source region 33 is provided in a portion of body region 32. Source region 33 has n type conductivity. Source region 33 has an impurity added therein, such as phosphorus (P).

Each of contact regions 34 has p type conductivity. Contact region 34 is provided in body region 32 and surrounded by body region 32, and is adjacent to source region 33. At the same depth position, contact region 34 preferably has an impurity concentration larger than the impurity concentration of body region 32.

Gate oxide film 41 is provided on upper surface P2 to cover surface portion 31c and body regions 32. In this way, gate oxide film 41 is provided on body regions 32 so as to connect surface portion 31c, which is a portion having n type conductivity in epitaxial substrate 39, and source regions 33 to each other. Gate oxide film 41 is formed of, for example, silicon dioxide (SiO₂). Gate electrode 42 is provided on gate oxide film 41. Gate electrode 42 is formed of a conductor, for example, is formed of a metal, such as polysilicon having an impurity added therein or Al, or an alloy.

Source electrode 51 is in contact with each of source regions 33 and contact regions 34. Drain electrode 61 is provided on backside surface P1 of epitaxial substrate 39. Source electrode 51 and drain electrode 61 are ohmic electrodes. Each of source electrode 51 and drain electrode 61 is preferably formed of a silicide, such as nickel silicide (NiₓSi_{y}).

Interlayer insulating film 43 covers gate electrode 42. Interlayer insulating film 43 is formed of, for example, silicon dioxide (SiO₂). Source interconnection layer 52 has a portion disposed on interlayer insulating film 43 and a portion disposed on source electrode 51. Source interconnection layer 52 is preferably formed of a metal or an alloy, for example, is formed of aluminum.

The following describes a method for manufacturing MOSFET 100.

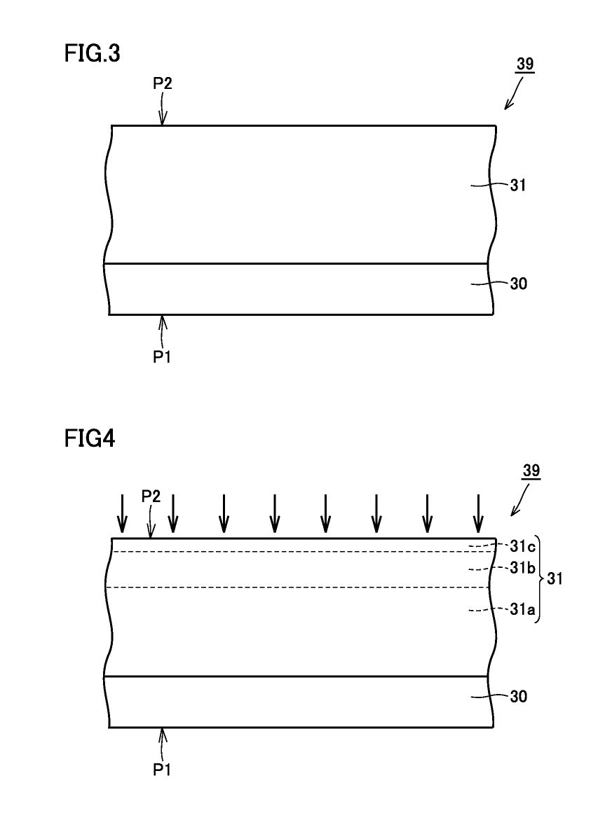

As shown in FIG. 3, drift region 31 is formed by means of epitaxial growth on single-crystal substrate 30. In this way, epitaxial substrate 39 is prepared which has backside surface P1 and upper surface P2 and has a donor added therein.

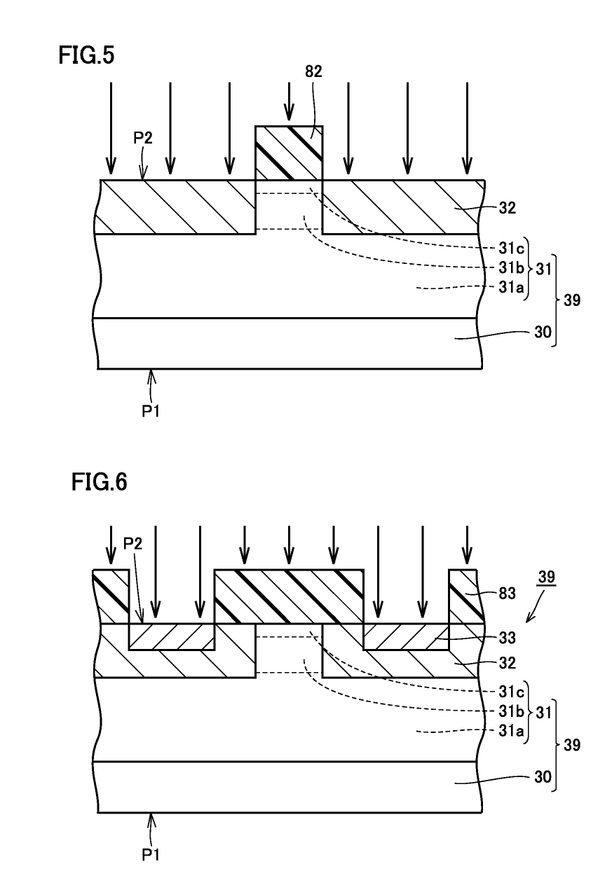

As indicated by arrows in FIG. 4, a donor is implanted into upper surface P2 of epitaxial substrate 39, i.e., into drift region 31. This implantation is performed such that a dose amount per volume in a region from depth position t₁ to depth position t₂ shallower than depth position t₁ becomes larger than each of a dose amount per volume in a region deeper than depth position t₁ and a dose amount per volume in a region from upper surface P2 to depth position t₂. As a result, breakdown voltage holding portion 31a, JFET portion 31b, and surface portion 31c are provided in drift region 31. This implantation is performed without using an implantation mask.

As shown in FIG. 5, an acceptor is implanted into upper surface P2 of epitaxial substrate 39 using an implantation mask 82 such that body regions 32 are formed in the portions of upper surface P2 of epitaxial substrate 39. This implantation is performed such that the dose amount per volume has a peak between depth position t₁ and depth position t₂.

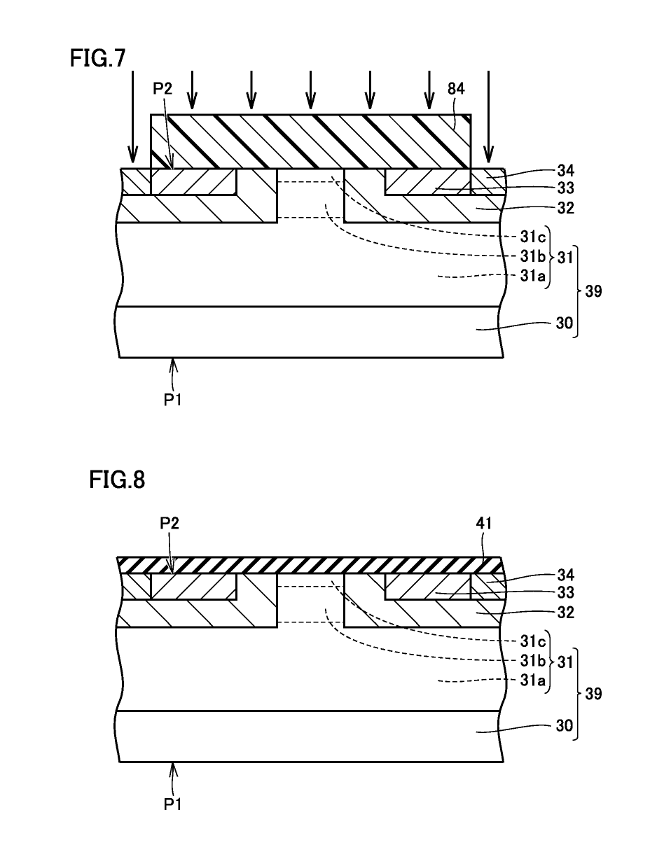

As shown in FIG. 6, by implanting a donor into portions of body regions 32 using an implantation mask 83, source regions 33 are formed. It should be noted that the implantation of donor may be performed before the formation of body regions 32 shown in FIG. 5. That is, the donor may be implanted into regions to serve as body regions 32, rather than body regions 32 having been already formed.

As shown in FIG. 7, contact regions 34 are formed by implanting an acceptor into portions of upper surface P2 using an implantation mask 84.

Next, in order to activate the impurities thus implanted, activation annealing is performed. For example, the activation annealing is performed under an argon (Ar) atmosphere at an annealing temperature of 1700° C. for an annealing time of 30 minutes. It should be noted that each of the above-described ion implantations may be performed in any order before the activation annealing.

As shown in FIG. 8, gate insulating film 41 is formed on upper surface P2 of epitaxial substrate 39. Gate oxide film 41 is formed on body region 32 to connect surface portion 31c (portion having n type conductivity in epitaxial substrate 39) and source regions 33 to each other. Gate oxide film 41 can be formed through, for example, thermal oxidation of silicon carbide in an oxygen atmosphere. For example, it is performed at an annealing temperature of 1300° C. for an annealing time of 60 minutes.

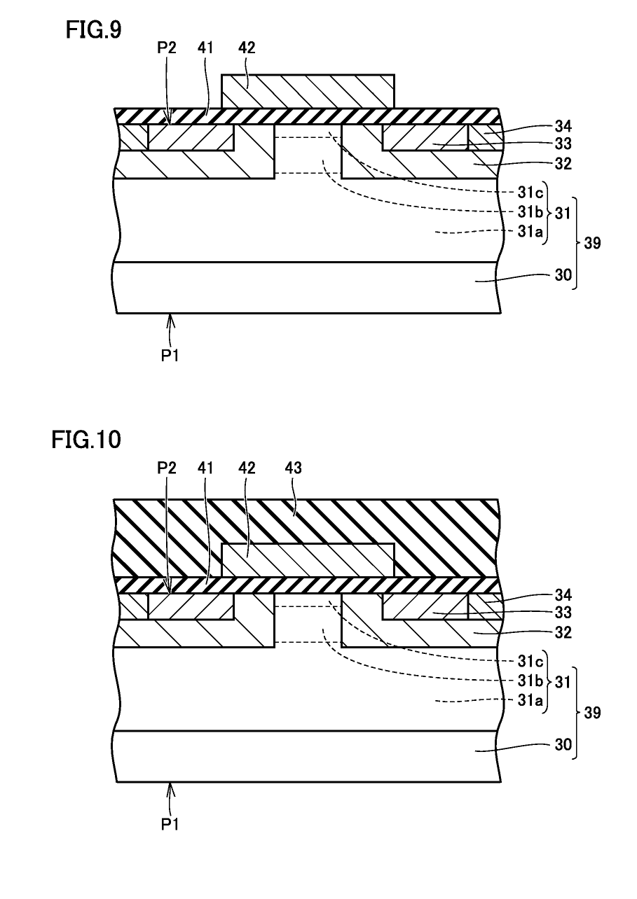

As shown in FIG. 9, gate electrode 42 is formed on gate oxide film 41. As shown in FIG. 10, interlayer insulating film 43 is deposited to cover gate electrode 42.

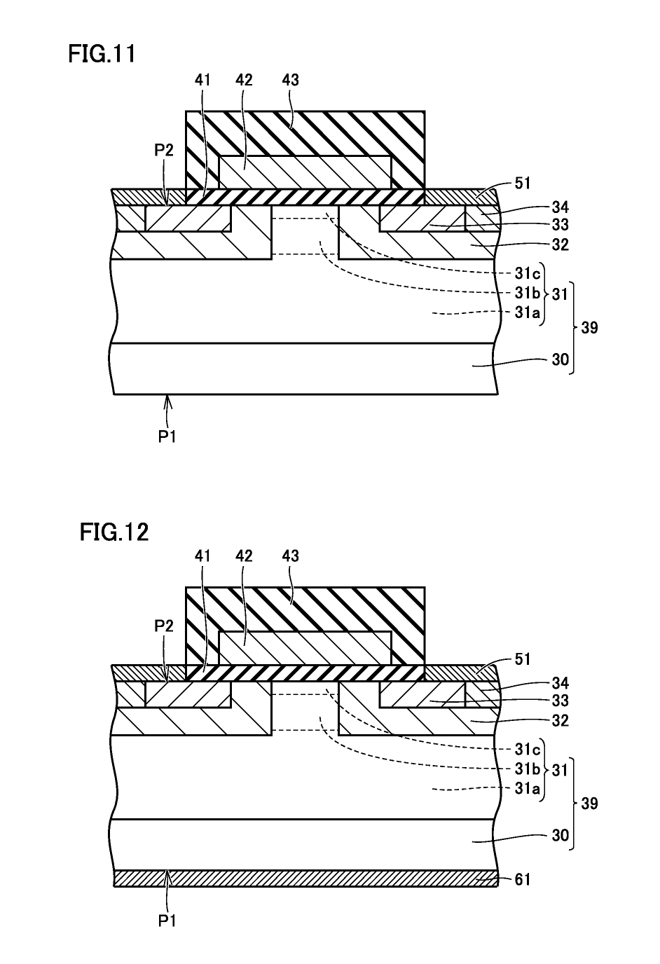

Referring to FIG. 11, in order to secure regions in which source electrodes 51 are to be formed, portions of interlayer insulating film 43 and gate oxide film 41 are removed. Source electrodes 51 are formed in contact with source regions 33 and contact regions 34. For example, nickel (Ni) films are formed using a deposition method and are then silicided.

As shown in FIG. 12, a drain electrode 61 is formed on backside surface P1 of epitaxial substrate 39. For example, nickel (Ni) films are formed using a deposition method and are then silicided.

Referring to FIG. 1 again, source interconnection layer 52 is formed using, for example, the deposition method. In this way, MOSFET 100 is obtained.

According to the present embodiment, as shown in FIG. 2, impurity concentration N₁ of breakdown voltage holding portion 31a is made lower than impurity concentration N₂ of JFET portion 31b. In this way, the depletion layer is facilitated to extend in breakdown voltage holding portion 31a. Therefore, dielectric breakdown of epitaxial substrate 39 is suppressed. Likewise, because impurity concentration N₃ of surface portion 31c is made lower than impurity concentration N₂ of JFET portion 31b of epitaxial substrate 39, the depletion layer is facilitated to extend in surface portion 31c. This reduces the electric field applied to gate oxide film 41 facing surface portion 31c. Therefore, dielectric breakdown of gate oxide film 41 is suppressed. That is, dielectric breakdown is suppressed in each of epitaxial substrate 39 and gate oxide film 41. This provides an increased breakdown voltage of MOSFET 100.

Moreover, as shown in FIG. 2, in the vicinity of upper surface P2 (in the vicinity of Z=0), i.e., in the region serving as a channel, body region 32 has an impurity concentration lower than that in the portion between depth position t₁ and depth position t₂. This leads to increased channel mobility. Moreover, at the portion between depth position t₁ and depth position t₂, body region 32 has an impurity concentration higher than that in the vicinity of upper surface P2. Accordingly, a punch through phenomenon can be suppressed.

Moreover, impurity concentration N₂ of JFET portion 31b is made higher than impurity concentration N₁ of breakdown voltage holding portion 31a. Accordingly, the depletion layer can be suppressed from extending from body region 32 to JFET portion 31b. Accordingly, the so-called JFET resistance becomes small. Such extension of the depletion layer is likely to progress particularly at depth position tₘₐₓ, at which concentration peak CP of body region 32 exists. According to the present embodiment, because JFET portion 31b having a high impurity concentration is positioned at depth position tₘₐₓ, the extension of the depletion layer can be suppressed effectively. In this way, the on-resistance of MOSFET 100 can be made low.

Moreover, when surface portion 31c of epitaxial substrate 39 has a thickness of not less than 5 nm, the electric field applied to gate oxide film 41 facing surface portion 31c can be made smaller. When surface portion 31c has a thickness of not more than 10 nm, JFET portion 31b having a resistivity lower than that in surface portion 31c is provided up to a shallower position, so that the on-resistance of MOSFET 100 can be made lower.

### Second Embodiment

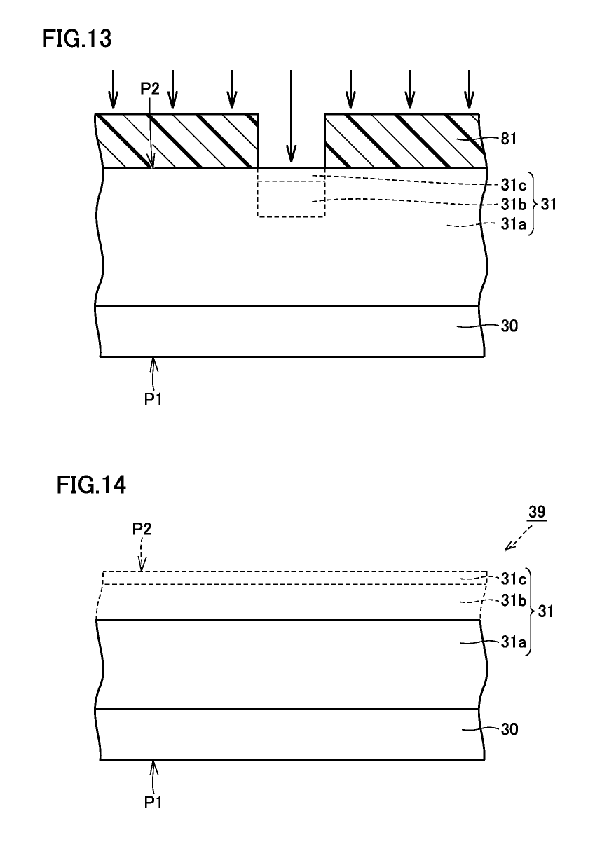

As shown in FIG. 13, in the present embodiment, during formation of JFET portion 31b and surface portion 31c, implantation is performed using an implantation mask 81 instead of performing the implantation of donor (FIG. 4) without using an implantation mask. Implantation mask 81 covers at least a portion of the regions to serve as body regions 32 (or body regions 32 having been already formed). Accordingly, in body regions 32 of MOSFET 100 (FIG. 1), the donor and acceptor are cancelled with each other at a smaller degree. In other words, an amount of impurities providing substantially no contribution to the conductivity types can be reduced. Therefore, the channel resistance on body region 32 can be made low, so that the on-resistance of MOSFET 100 can be made lower.

It should be noted that configurations other than the above are substantially the same as those of the first embodiment. Hence, the same or corresponding elements are given the same reference characters and are not described repeatedly.

### Third Embodiment

As shown in FIG. 14, in the present embodiment, breakdown voltage holding portion 31a is grown epitaxially on single-crystal substrate 30 to have impurity concentration N₁. Next, on breakdown voltage holding portion 31a, JFET portion 31b is grown epitaxially to have impurity concentration N₂. Next, on JFET portion 31b, surface portion 31c is grown epitaxially to have impurity concentration N₃. In this way, epitaxial substrate 39 is prepared. Thereafter, the same steps as those in FIG. 5 to FIG. 12 are performed, thereby obtaining a MOSFET substantially the same as MOSFET 100 (FIG. 1).

According to the present embodiment, a difference in impurity concentration among breakdown voltage holding portion 31a, JFET portion 31b, and surface portion 31c in epitaxial substrate 39 can be adjusted during each of the epitaxial growths.

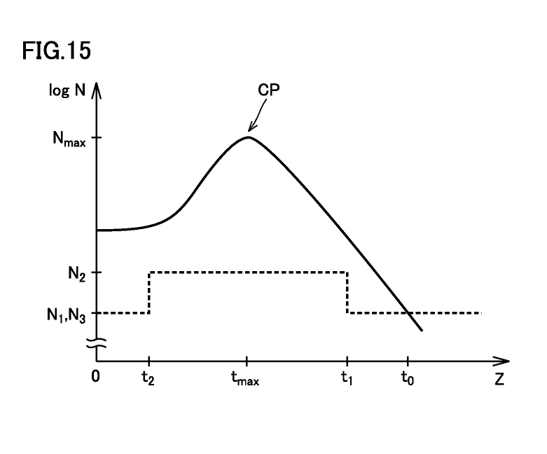

It should be noted that, in each of the above-described embodiments, impurity concentration N₁ of breakdown voltage holding portion 31a and impurity concentration N₃ of surface portion 31c may be the same as shown in FIG. 15. In this case, breakdown voltage holding portion 31a, JFET portion 31b, and surface portion 31c can be provided only by implanting the donor between depth t₁ and depth t₂ in the implantation step (FIG. 4) after forming an epitaxial layer having impurity concentration N₁═N₃. Accordingly, the method for manufacturing MOSFET 100 is simplified.

It should be noted that the impurity concentrations can be measured through, for example, SIMS (Secondary Ion Mass Spectroscopy). Moreover, in the impurity concentration profile (each of FIG. 2 and FIG. 15), depth position t₀ is positioned deeper than depth position t₁, but depth position t₁ may be positioned deeper than depth position t₀.

Moreover, the first and second conductivity types should be different conductivity types, so that the first conductivity type may correspond to p type, and the second conductivity type may correspond to n type. However, in the case where the first conductivity type corresponds to n type and the second conductivity type corresponds to p type, channel resistance can be smaller than that in the case where the first conductivity type corresponds to p type and the second conductivity type corresponds to n type. Further, the gate insulating film is not limited to the oxide film. Hence, the silicon carbide semiconductor device may be a MISFET (Metal Insulator Semiconductor Field Effect Transistor) other than the MOSFET. Further, the silicon carbide semiconductor device is not limited to the MISFET, and may be, for example, an IGBT (Insulated Gate Bipolar Transistor).

The embodiments disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

30: single-crystal substrate; 31: drift region; 31a: breakdown voltage holding portion; 31b: JFET portion; 31c: surface portion; 32: body region; 33: source region; 34: contact region; 39: epitaxial substrate (silicon carbide substrate); 41: gate oxide film (gate insulating film); 42: gate electrode; 43: interlayer insulating film; 51: source electrode (second main electrode); 52: source interconnection layer; 61: drain electrode (first main electrode); 100: MOSFET (silicon carbide semiconductor device).

1. A silicon carbide semiconductor device comprising:
a silicon carbide substrate having a first main surface and a second main surface opposite to said first main surface and having an impurity for providing a first conductivity type, said silicon carbide substrate including a first portion, a second portion, and a third portion, said first portion being disposed deeper than a first depth position based on said second main surface as a reference, said second portion being disposed to extend from said first depth position to a second depth position shallower than said first depth position, said third portion being disposed to extend from said second depth position to said second main surface, said first to third portions respectively having first to third impurity concentrations, said second impurity concentration being higher than said first impurity concentration, said third impurity concentration being not less than said first impurity concentration and being less than said second impurity concentration;
a body region provided on a portion of said second main surface of said silicon carbide substrate and having an impurity for providing a second conductivity type, said body region having a concentration peak of said impurity, for providing the second conductivity type, at a depth position shallower than said first depth position and deeper than said second depth position;
a source region provided on a portion of said body region and having said first conductivity type;
a gate insulating film provided on said body region to connect a portion, which has said first conductivity type in said silicon carbide substrate, and said source region to each other;
a gate electrode provided on said gate insulating film;
a first main electrode provided on said first main surface of said silicon carbide substrate; and
a second main electrode in contact with said source region.

2. The silicon carbide semiconductor device according to claim 1, wherein said second portion of said silicon carbide substrate contains an impurity provided by ion implantation.

3. The silicon carbide semiconductor device according to claim 1, wherein said third impurity concentration is equal to said first impurity concentration.

4. The silicon carbide semiconductor device according to claim 1, wherein said third impurity concentration is higher than said first impurity concentration.

5. The silicon carbide semiconductor device according to claim 1, wherein said third portion has a thickness of not less than 5 nm and not more than 10 nm.

6. A method for manufacturing a silicon carbide semiconductor device, comprising the steps of:
preparing a silicon carbide substrate having a first main surface and a second main surface opposite to said first main surface and having an impurity for providing a first conductivity type;
implanting said impurity for providing said first conductivity type into said second main surface of said silicon carbide substrate such that a dose amount per volume in a region from a first depth position to a second depth position shallower than said first depth position becomes larger than each of a dose amount per volume in a region deeper than said first depth position and a dose amount per volume in a region from said second main surface to said second depth position;
implanting an impurity for providing a second conductivity type into said second main surface of said silicon carbide substrate such that a body region having said second conductivity type is formed in a portion of said second main surface of said silicon carbide substrate, the step of implanting said impurity for providing said second conductivity type being performed such that the dose amount per volume has a peak between said first depth position and said second depth position;
forming a source region having said first conductivity type by implanting said impurity for providing said first conductivity type into a portion of one of said body region and a region to serve as said body region;
forming a gate insulating film on said body region to connect a portion, which has said first conductivity type in said silicon carbide substrate, and said source region to each other;
forming a gate electrode on said gate insulating film;
forming a first main electrode on said first main surface of said silicon carbide substrate; and
forming a second main electrode in contact with said source region.

7. The method for manufacturing the silicon carbide semiconductor device according to claim 6, wherein the step of implanting said impurity for providing said first conductivity type into said second main surface of said silicon carbide substrate is performed without using an implantation mask.

8. The method for manufacturing the silicon carbide semiconductor device according to claim 6, wherein the step of implanting said impurity for providing said first conductivity type into said second main surface of said silicon carbide substrate is performed using an implantation mask that covers at least a portion of one of said body region and a region to serve as said body region.

9. A method for manufacturing a silicon carbide semiconductor device, comprising the steps of:
preparing a silicon carbide substrate having a first main surface and a second main surface opposite to said first main surface and having an impurity for providing a first conductivity type, said silicon carbide substrate including a first portion, a second portion, and a third portion, said first portion being disposed deeper than a first depth position based on said second main surface as a reference, said second portion being disposed to extend from said first depth position to a second depth position shallower than said first depth position, said third portion being disposed to extend from said second depth position to said second main surface, said first to third portions respectively having first to third impurity concentrations, said second impurity concentration being higher than said first impurity concentration, said third impurity concentration being not less than said first impurity concentration and being less than said second impurity concentration, the step of preparing said silicon carbide substrate including the steps of epitaxially growing said first portion on a single-crystal substrate to have said first impurity concentration, epitaxially growing said second portion on said first portion to have said second impurity concentration, and epitaxially growing said third portion on said second portion to have said third impurity concentration;
implanting an impurity for providing a second conductivity type into said second main surface of said silicon carbide substrate such that a body region having said second conductivity type is formed in a portion of said second main surface of said silicon carbide substrate, the step of implanting said impurity for providing said second conductivity type being performed such that a dose amount per volume has a peak between said first depth position and said second depth position;
forming a source region having said first conductivity type by implanting said impurity for providing said first conductivity type into a portion of one of said body region and a region to serve as said body region;
forming a gate insulating film on said body region to connect a portion, which has said first conductivity type in said silicon carbide substrate, and said source region to each other;
forming a gate electrode on said gate insulating film;
forming a first main electrode on said first main surface of said silicon carbide substrate; and
forming a second main electrode in contact with said source region.
